(19) United States
(12) Patent Application Publication
(10) Pub. No.: US 2025/0298096 A1
(43) Pub. Date: Sep. 25, 2025

(54) MAGNETIC SENSOR DEVICE, MAGNETIC SENSOR SYSTEM, AND CORRECTION METHOD

(71) Applicant: TDK CORPORATION, Tokyo (JP)

(72) Inventors: Norikazu OTA, Tokyo (JP); Koichi Otani, Tokyo (JP); Keita Miyachi, Tokyo (JP)

(73) Assignee: TDK CORPORATION, Tokyo (JP)

(21) Appl. No.: 19/072,149

(22) Filed: Mar. 6, 2025

(30) Foreign Application Priority Data
Mar. 19, 2024 (JP) 2024-044086

(51) Int. Cl. G01R 33/00; G01R 33/09

(52) U.S. Cl. CPC G01R 33/0029; G01R 33/0035; G01R 33/093; G01R 33/096; G01R 33/098

(57) ABSTRACT

A magnetic sensor device includes a magnetic sensor, a magnetic field generator, and a processor. The processor generates first sensitivity that indicates sensitivity of the magnetic sensor when a strength of an additional magnetic field is changed in a first range, generates second sensitivity that indicates sensitivity of the magnetic sensor when the strength of the additional magnetic field is changed in a second range, and generates a detection value corresponding to a component of a magnetic field, based on a detection signal, the first sensitivity, and the second sensitivity.

### CROSS REFERENCE TO RELATED APPLICATIONS

This application claims the benefit of Japanese Priority Patent Application No. 2024-44086 filed on Mar. 19, 2024, the entire contents of which are incorporated herein by reference.

### BACKGROUND

The technology relates to a magnetic sensor device with a magnetic field generator, a magnetic sensor system including the magnetic sensor device, and a method for correcting a detection signal of the magnetic sensor.

Magnetic sensors capable of detecting an external magnetic field have recently been used in a variety of applications. A type of magnetic sensor uses a magnetic detection element. An example of the magnetic detection element is a magnetoresistive element.

US 2016/0273915 A1 discloses a correcting device of geomagnetic data.

US 2020/0116801 A1 and US 2020/0191547A1 each discloses a magnetic sensor device including three magnetic sensors and a magnetic field generation unit that generates additional magnetic field components in three directions.

In the magnetic sensor configured to detect three components in three directions, in some cases, a complicated computation may be needed to correct each offset of the three detection signals, for example as disclosed in US 2016/0273915 A1. In such a case, a load of a processor may be increased.

### SUMMARY

A magnetic sensor device according to one embodiment of the technology includes: a magnetic sensor configured to detect a component of a magnetic field and generate a detection signal; a magnetic field generator configured to generate an additional magnetic field to measure sensitivity of the magnetic sensor in a direction of the component of the magnetic field; and a processor. The processor is configured to: receive the detection signal; generate first sensitivity that indicates the sensitivity of the magnetic sensor when a strength of the additional magnetic field is changed in a first range; generate second sensitivity that indicates the sensitivity of the magnetic sensor when the strength of the additional magnetic field is changed in a second range; and generate a detection value corresponding to the component of the magnetic field, based on the detection signal, the first sensitivity, and the second sensitivity.

A magnetic sensor system according to one embodiment of the technology includes the magnetic sensor device according to the one embodiment of the technology, and an external processor. The detection signal includes a first signal, a second signal, and a third signal that have correspondences with components in three mutually different directions of the magnetic field at a reference position. The external processor generates data on center coordinates of a virtual sphere having a spherical surface in an orthogonal coordinate system defined by three axes indicating values of the first signal, the second signal, and the third signal, the spherical surface approximating a distribution of a plurality of measurement points in a plurality of timings. Each of the plurality of measurement points represents coordinates in the orthogonal coordinate system corresponding to a set of values of the first signal, the second signal, and the third signal at a certain timing. The processor of the magnetic sensor device corrects an offset of each of the first signal, the second signal, and the third signal by referring to the data on the center coordinates.

A correction method according to one embodiment of the technology is a correction method for a magnetic sensor configured to detect a magnetic field. The correction method according to the one embodiment of the technology includes: applying an additional magnetic field to the magnetic sensor, the additional magnetic field being used to measure sensitivity of the magnetic sensor; generating first sensitivity that indicates the sensitivity of the magnetic sensor while changing a strength of the additional magnetic field in a first range; generating second sensitivity that indicates the sensitivity of the magnetic sensor while changing the strength of the additional magnetic field in a second range; generating a first value indicating a correspondence with a strength of a component of the magnetic field applied to the magnetic sensor, based on the first sensitivity and the second sensitivity; generating a second value indicating a correspondence with the strength of the component of the magnetic field applied to the magnetic sensor, based on a detection signal of the magnetic sensor; and correcting an offset of the detection signal based on the first value and the second value.

Other and further objects, features, and advantages of the technology will become apparent more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view showing a magnetic sensor device according to a first example embodiment of the technology.

FIG. 2 is a functional block diagram showing a configuration of the magnetic sensor device according to the first example embodiment of the technology.

FIG. 3 is a plan view showing the magnetic sensor device according to the first example embodiment of the technology.

FIG. 4 is a circuit diagram showing circuit configurations of a first detection circuit and a second detection circuit of the first example embodiment of the technology.

FIG. 5 is a perspective view showing a part of a resistor section of the first example embodiment of the technology.

FIG. 6 is a perspective view showing a magnetoresistive element of the first example embodiment of the technology.

FIG. 7 is a circuit diagram showing a circuit configuration of a third detection circuit of the first example embodiment of the technology.

FIG. 8 is a perspective view showing a part of the third detection circuit of the first example embodiment of the technology.

FIG. 9 is a plan view showing a part of the third detection circuit of the first example embodiment of the technology.

FIG. 10 is a side view showing a part of the third detection circuit of the first example embodiment of the technology.

FIG. 11 is a characteristic chart showing an example of a relationship between a first magnetic field component and a first detection signal of the first example embodiment of the technology.

FIG. 12 is a characteristic chart showing an example of a relationship between a third magnetic field component and a third detection signal of the first example embodiment of the technology.

FIG. 13 is a characteristic chart showing an example of a relationship between the third magnetic field component and a sensitivity change of the first example embodiment of the technology.

FIG. 14 is a flowchart showing a correction method according to the first example embodiment of the technology.

FIG. 15 is a characteristic chart showing a linearity of the third detection signal of the first example embodiment of the technology.

FIG. 16 is a functional block diagram showing a configuration of a magnetic sensor system according to a second example embodiment of the technology.

### DETAILED DESCRIPTION

An object of the technology is to provide a magnetic sensor device, a magnetic sensor system, and a correction method that enable reduction of a detection error of a magnetic sensor with a simple method.

In the following, some example embodiments and modification examples of the technology are described in detail with reference to the accompanying drawings. Note that the following description is directed to illustrative examples of the disclosure and not to be construed as limiting the technology. Elements including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Similar elements are denoted with the same reference numerals to avoid redundant descriptions. Note that the description is given in the following order.

### First Example Embodiment

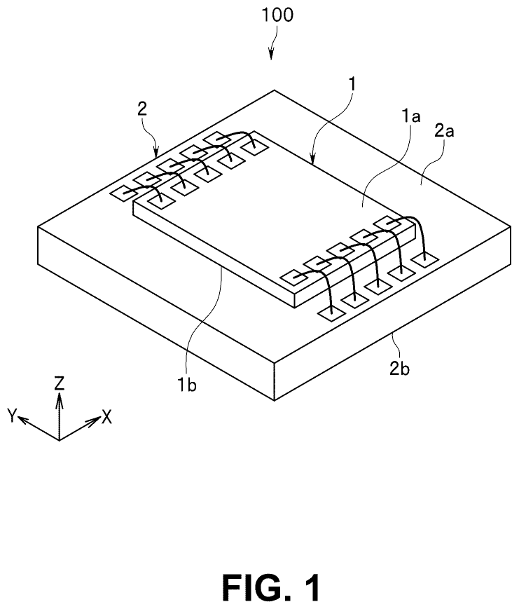

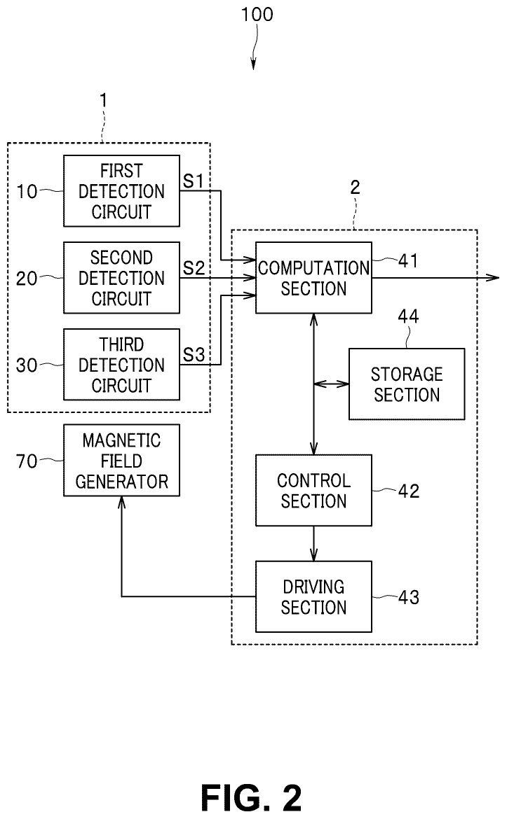

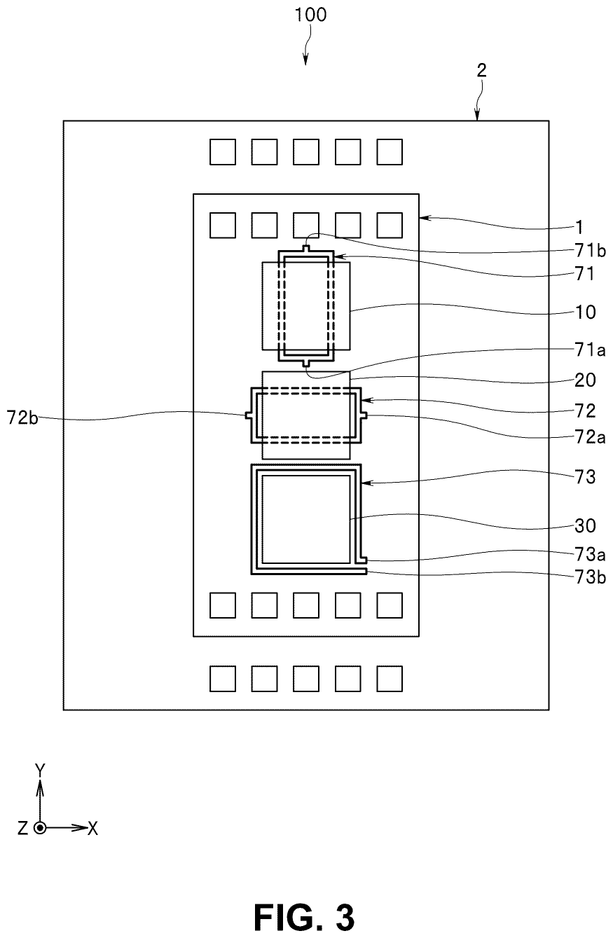

In the following, some example embodiments of the technology are described in detail with reference to the accompanying drawings. A magnetic sensor device 100 according to the first example embodiment of the technology will initially be described with reference to FIGS. 1 to 3. FIG. 1 is a perspective view showing the magnetic sensor device 100 according to the example embodiment. FIG. 2 is a functional block diagram showing a configuration of the magnetic sensor device 100 according to the example embodiment. FIG. 3 is a plan view showing the magnetic sensor device 100 according to the example embodiment.

The magnetic sensor device 100 includes a magnetic sensor 1, a processor 2, and a magnetic field generator 70. The magnetic sensor 1 is configured to detect a target magnetic field which is a magnetic field to be detected, to output at least one detection signal. The processor 2 is configured to receive the at least one detection signal. The magnetic field generator 70 is configured to generate at least one additional magnetic field used for measuring sensitivity of the magnetic sensor 1. The target magnetic field may be geomagnetism, a magnetic field generated by a magnet, or a magnetic field generated by wiring through which a current flows. In the example embodiment, in particular, the target magnetic field is a magnetic field other than the geomagnetism. The example in which the target magnetic field is the geomagnetism will be described in a second example embodiment.

As shown in FIG. 1, the magnetic sensor 1 is configured as a first chip. In addition, the processor 2 is configured as a second chip different from the first chip. The magnetic sensor 1 and the processor 2 each have a rectangular solid shape. The magnetic sensor 1 includes a top surface 1a and a bottom surface 1b located on opposite sides of each other, and four side surfaces connecting the top surface 1a and the bottom surface 1b. The outer surface of the processor 2 includes a top surface 2a and a bottom surface 2b located on opposite sides of each other, and four side surfaces connecting the top surface 2a and the bottom surface 2b. The magnetic sensor 1 may be mounted on the top surface 2a of the processor 2 in such an orientation that the bottom surface 1b faces the top surface 2a of the processor 2.

The magnetic sensor 1 includes a plurality of electrode pads disposed on the top surface 1a. The processor 2 includes a plurality of electrode pads disposed on the top surface 2a. The plurality of electrode pads of the magnetic sensor 1 are connected to the plurality of electrode pads of the processor 2 via a plurality of bonding wires, for example.

Now, a description will be given of a reference coordinate system in the example embodiment with reference to FIGS. 1 and 3. The reference coordinate system is an orthogonal coordinate system that is set with reference to the magnetic sensor 1. An X direction, a Y direction, and a Z direction are defined in the reference coordinate system. As shown in FIG. 3, the X, Y, and Z directions are orthogonal to each other. The opposite directions to the X, Y, and Z directions will be expressed as −X, −Y, and −Z directions, respectively.

Hereinafter, in the reference coordinate system, the term “above” refers to positions located forward of a reference position in the Z direction, and “below” refers to positions opposite from the “above” positions with respect to the reference position. For each component of the magnetic sensor 1, the term “top surface” refers to a surface of the component lying at the end thereof in the Z direction, and “bottom surface” refers to a surface of the component lying at the end thereof in the-Z direction. The expression “when seen in the Z direction” means that the intended object is seen from a position at a distance in the Z direction.

The magnetic sensor 1 includes a first detection circuit 10 for generating at least one first detection signal, a second detection circuit 20 for generating at least one second detection signal, and a third detection circuit 30 for generating at least one third detection signal. Each of the first to third detection circuits 10, 20, and 30 includes at least one magnetic detection element. In the example embodiment, in particular, each of the first to third detection circuits 10, 20, and 30 includes a plurality of magnetoresistive elements (hereinafter, referred to as MR elements) as at least one magnetic detection element.

At least one first detection signal, at least one second detection signal, and at least one third detection signal have correspondences respectively with the components in three directions of the target magnetic field at a reference position (position where the magnetic sensor 1 is disposed, for example). The three directions are different from one another. In the example embodiment, at least one first detection signal has a correspondence with a first magnetic field component MFx of the target magnetic field. The first magnetic field component is a component in a direction parallel to the X direction. At least one second detection signal has a correspondence with a second magnetic field component MFy of the target magnetic field. The second magnetic field component is a component in a direction parallel to the Y direction. At least one third detection signal has a correspondence with a third magnetic field component MFz of the target magnetic field. The third magnetic field component is a component in a direction parallel to the Z direction.

The first detection circuit 10 is configured to detect the first magnetic field component MFx, to output at least one first detection signal. The second detection circuit 20 is configured to detect the second magnetic field component MFy, to output at least one second detection signal. The third detection circuit 30 is configured to detect the third magnetic field component MFz, to output at least one third detection signal.

The magnetic field generator 70 includes a first coil 71 configured to generate a first additional magnetic field, a second coil 72 configured to generate a second additional magnetic field, and a third coil 73 configured to generate a third additional magnetic field. The first additional magnetic field is used for measuring the sensitivity of the first detection circuit 10. The second additional magnetic field is used for measuring the sensitivity of the second detection circuit 20. The third additional magnetic field is used for measuring the sensitivity of the third detection circuit 30. Each of the first to third additional magnetic fields may be a static magnetic field or an alternating magnetic field.

In the example shown in FIG. 3, the first coil 71 is arranged so as to overlap the first detection circuit 10 when seen in the Z direction. The second coil 72 is arranged so as to overlap the second detection circuit 20 when seen in the Z direction. The third coil 73 is arranged so that the third detection circuit 30 is included inside the third coil 73 when seen in the Z direction. The first to third coils 71 to 73 may be arranged at positions other than the positions shown in FIG. 3, as long as the first to third additional magnetic fields can be used respectively for measuring the sensitivities of the first, second, and third detection circuits 10, 20, and 30.

The first to third coils 71 to 73 may be arranged between the top surface 1a of the magnetic sensor 1 and the bottom surface 2b of the processor 2. The first to third coils 71 to 73 may be provided in the magnetic sensor 1 which is the first chip, or may be provided in the processor 2 which is the second chip. In the case where the first to third coils 71 to 73 are provided in the processor 2, the first to third coils 71 to 73 may be arranged at positions closer to the top surface 2a than to the bottom surface 2b.

The processor 2 includes a computation section 41, a control section 42, a driving section 43, and a storage section 44. The computation section 41 performs various kinds of computation based on at least one first detection signal, at least one second detection signal, and at least one third detection signal. The driving section 43 controls the magnetic field generator 70 to generate the first to third additional magnetic fields and to change the first to third additional magnetic fields. The control section 42 controls the computation section 41, the driving section 43, and the storage section 44. The storage section 44 may store various kinds of data to be described later.

The processor 2 may be constructed of an application-specific integrated circuit (ASIC), for example.

Note that the magnetic sensor device 100 may include, instead of the processor 2, a processor, not shown, that is not integrated with the magnetic sensor 1. The processor, not shown, may include a function of the processor 2. The processor, not shown, may be constructed of an ASIC or a microcomputer, for example.

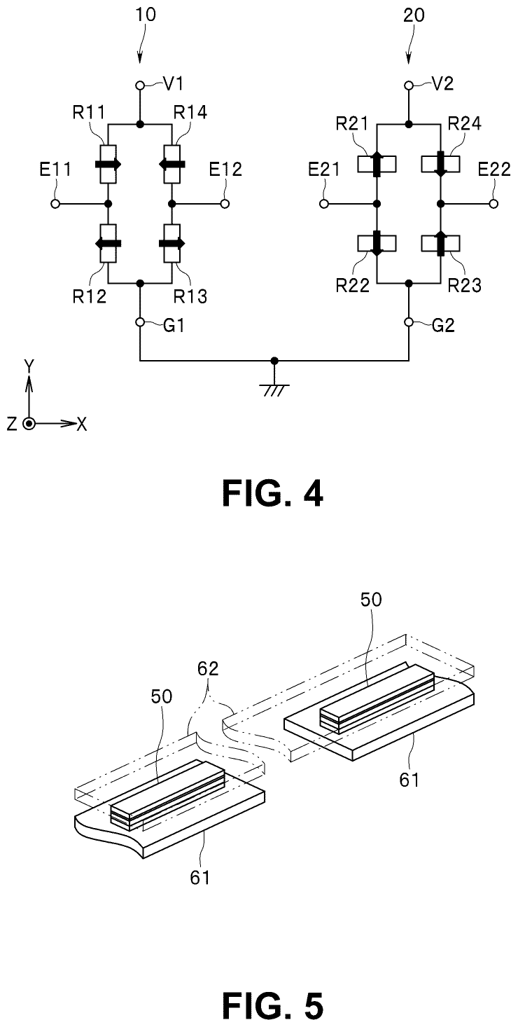

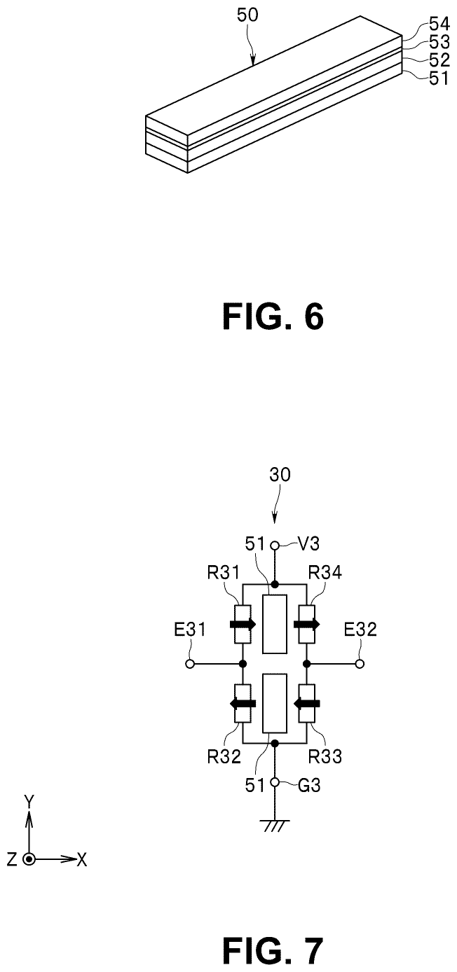

Next, configurations of the first and second detection circuits 10 and 20 will be described with reference to FIGS. 4 to 6. FIG. 4 is a circuit diagram showing circuit configurations of the first and second detection circuits 10 and 20. FIG. 5 is a perspective view showing a part of a resistor section. FIG. 6 is a perspective view showing an MR element.

As shown in FIG. 4, the first detection circuit 10 includes a power supply port V1, a ground port G1, output ports E11 and E12, and resistor sections R11, R12, R13, and R14. A plurality of MR elements of the first detection circuit 10 constitute the resistor sections R11 to R14.

The resistor section R11 is provided between the power supply port V1 and the output port E11. The resistor section R12 is provided between the output port E11 and the ground port G1. The resistor section R13 is provided between the output port E12 and the ground port G1. The resistor section R14 is provided between the power supply port V1 and the output port E12. A voltage or a current of predetermined magnitude is applied to the power supply port V1. The ground port G1 is connected to the ground.

The second detection circuit 20 includes a power supply port V2, a ground port G2, output ports E21 and E22, and resistor sections R21, R22, R23, and R24. A plurality of MR elements of the second detection circuit 20 constitute the resistor sections R21 to R24.

The resistor section R21 is provided between the power supply port V2 and the output port E21. The resistor section R22 is provided between the output port E21 and the ground port G2. The resistor section R23 is provided between the output port E22 and the ground port G2. The resistor section R24 is provided between the power supply port V2 and the output port E22. A voltage or a current of predetermined magnitude is applied to the power supply port V2. The ground port G2 is connected to the ground.

The plurality of MR elements will now be described. The MR element may be a spin-valve MR element or an AMR (anisotropic magnetoresistive) element. In particular, in the example embodiment, the MR element is a spin-valve MR element. The spin-valve MR element includes a magnetization pinned layer having a magnetization whose direction is fixed, a free layer having a magnetization whose direction is variable depending on the magnetic field applied to the magnetic sensor 1, and a gap layer located between the magnetization pinned layer and the free layer. The spin-valve MR element may be a TMR (tunneling magnetoresistive) element or a GMR (giant magnetoresistive) element. In the TMR element, the gap layer is a tunnel barrier layer. In the GMR element, the gap layer is a nonmagnetic conductive layer. The resistance of the spin-valve MR element changes with the angle that the magnetization direction of the free layer forms with respect to the magnetization direction of the magnetization pinned layer. The resistance of the spin-valve MR element is at its minimum value when the foregoing angle is 0°, and at its maximum value when the foregoing angle is 180°. The free layer has a shape anisotropy that sets the direction of the magnetization easy axis to be orthogonal to the magnetization direction of the magnetization pinned layer. As a method for setting the magnetization easy axis in a predetermined direction in the free layer, a magnet configured to apply a bias magnetic field to the free layer can be used.

FIG. 5 shows a part of any of the resistor sections R11 to R14 of the first detection circuit 10 and the resistor sections R21 to R24 of the second detection circuit 20. FIG. 5 shows an example in which CPP (Current Perpendicular-to-Plane) MR elements are connected in series. Any resistor section includes a plurality of lower electrodes 61, a plurality of MR elements 50, and a plurality of upper electrodes 62. The plurality of lower electrodes 61 are arranged on a substrate, not shown. Each of the lower electrodes 61 has a long slender shape. Every two lower electrodes 61 that are adjacent to each other in the longitudinal direction of the lower electrodes 61 have a gap therebetween. As shown in FIG. 5, the MR elements 50 are disposed near both longitudinal ends on the top surface of each lower electrode 61.

The MR element 50 shown in FIG. 6 includes an antiferromagnetic layer 51, a magnetization pinned layer 52, a gap layer 53, and a free layer 54 which are stacked in this order, from closest to farthest from the lower electrode 61. The antiferromagnetic layer 51 is electrically connected to the lower electrodes 61. The antiferromagnetic layer 51 is formed of an antiferromagnetic material, and is in exchange coupling with the magnetization pinned layer 52 to thereby pin the magnetization direction of the magnetization pinned layer 52.

As shown in FIG. 5, the plurality of upper electrodes 62 are arranged over the plurality of MR elements 50. Each upper electrode 62 has a long slender shape, and electrically connects the free layers 54 of two adjacent MR elements 50 that are disposed on two lower electrodes 61 adjacent to each other in the longitudinal direction of the lower electrodes 61. With such a configuration, any resistor section shown in FIG. 5 includes a plurality of MR elements 50 that are connected in series by the plurality of lower electrodes 61 and the plurality of upper electrodes 62.

The magnetization pinned layer 52 may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled. In a case where the magnetization pinned layer 52 is the self-pinned layer, the antiferromagnetic layer 51 may be omitted.

In addition, the layers 51 to 54 of each MR element 50 may be stacked in the reverse order to that shown in FIG. 6.

In addition, any resistor section may include a plurality of groups of MR elements 50 connected in parallel. The plurality of groups may be connected in series. In addition, the MR element 50 may be a CIP (Current In-Plane) MR element.

In FIG. 4, graphics representing the resistor sections R11 to R14 and R21 to R24 are shown, and each of the graphics schematically shows one MR element 50. In FIG. 4, the filled arrows represent the magnetization directions of the magnetization pinned layers 52 of the MR elements 50. In the example shown in FIG. 4, the magnetization pinned layers 52 of the MR elements 50 in each of the resistor sections R11 and R13 are magnetized in the X direction. The magnetization pinned layers 52 of the MR elements 50 in each of the resistor sections R12 and R14 are magnetized in the −X direction.

The magnetization pinned layers 52 of the MR elements 50 in each of the resistor sections R21 and R23 are magnetized in the Y direction. The magnetization pinned layers 52 of the MR elements 50 in each of the resistor sections R22 and R24 are magnetized in the −Y direction.

A potential difference between the output port E11 and the output port E12 has a correspondence with the first magnetic field component MFx. The first detection circuit 10 generates a first detection signal S1 corresponding to the potential difference between the output port E11 and the output port E12. Note that the first detection circuit 10 may generate, instead of the first detection signal S1, two signals corresponding respectively to the potential of the output port E11 and the potential of the output port E12, as two first detection signals.

A potential difference between the output port E21 and the output port E22 has a correspondence with the second magnetic field component MFy. The second detection circuit 20 generates a second detection signal S2 corresponding to the potential difference between the output port E21 and the output port E22. Note that the second detection circuit 20 may generate, instead of the second detection signal S2, two signals corresponding respectively to the potential of the output port E21 and the potential of the output port E22, as two second detection signals.

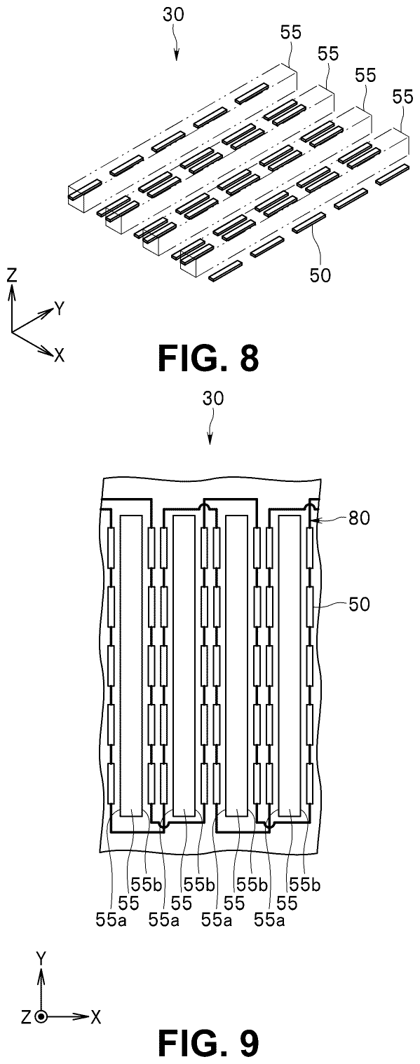

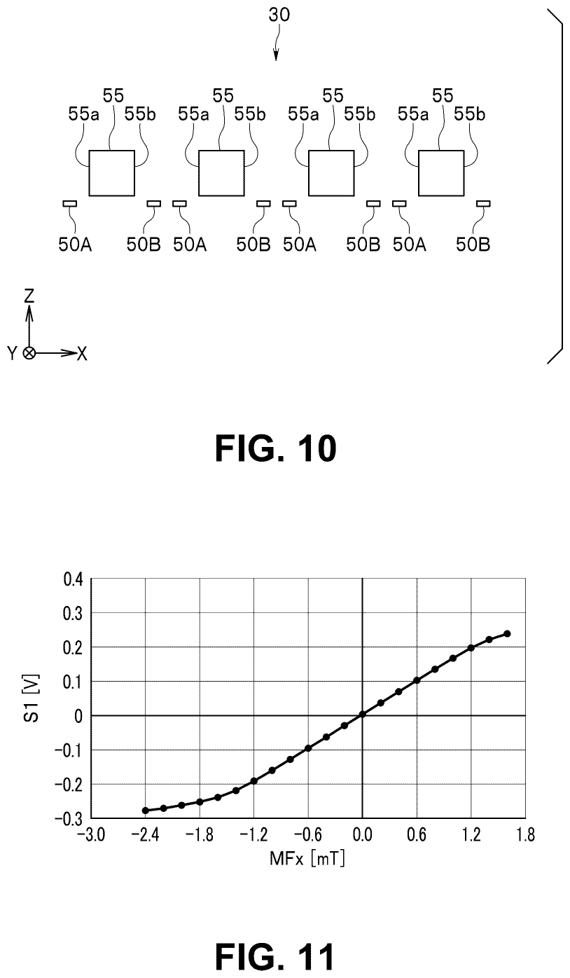

Hereinafter, a structure of the third detection circuit 30 will be described with reference to FIGS. 7 to 10. FIG. 7 is a circuit diagram showing a circuit configuration of the third detection circuit 30. FIG. 8 is a perspective view showing a part of the third detection circuit 30. FIG. 9 is a plan view showing a part of the third detection circuit 30. FIG. 10 is a side view showing a part of the third detection circuit 30.

As shown in FIG. 7, the third detection circuit 30 includes a power supply port V3, a ground port G3, output ports E31 and E32, and resistor sections R31, R32, R33, and R34. The plurality of MR elements 50 of the third detection circuit 30 constitute the resistor sections R31 to R34.

The resistor section R31 is provided between the power supply port V3 and the output port E31. The resistor section R32 is provided between the output port E31 and the ground port G3. The resistor section R33 is provided between the output port E32 and the ground port G3. The resistor section R34 is provided between the power supply port V3 and the output port E32. A voltage or a current of predetermined magnitude is applied to the power supply port V3. The ground port G3 is connected to the ground.

The third detection circuit 30 may further include at least one yoke formed of a soft magnetic body. The at least one yoke has a long shape in the Y direction when seen in the Z direction. In addition, the at least one yoke may be configured to generate a magnetic field component to be detected by the plurality of MR elements 50 of the third detection circuit 30, based on the magnetic field applied to the third detection circuit 30. In other words, the at least one yoke may be configured to receive the third magnetic field component MFz, and generate an output magnetic field. In the example embodiment, in particular, the output magnetic field includes, as the magnetic field component, an output magnetic field component in a direction parallel to the X direction. The output magnetic field component changes according to the third magnetic field component MFz.

As shown in FIGS. 8 to 10, in the example embodiment, in particular, the third detection circuit 30 includes a plurality of yokes 55 arranged in the X direction, as the at least one yoke. Each of the plurality of yokes 55 has a rectangular solid shape long in the Y direction, for example. The plurality of yokes 55 have the same shape. Each of the plurality of yokes 55 has a first end face 55a and a second end face 55b located at both ends in the direction parallel to the X direction. The first end face 55a of each of the plurality of yokes 55 is located at the end of the yoke 55 in the −X direction, and the second end face 55b is located at the end of the yoke 55 in the X direction.

As shown in FIGS. 8 and 9, in the third detection circuit 30, a plurality of MR elements 50 are arranged in a row along the first end face 55a, and a plurality of MR elements 50 are arranged in a row along the second end face 55b. Hereinafter, the plurality of MR elements 50 arranged along the first end face 55a are represented by the reference numeral 50A, and the plurality of MR elements 50 arranged along the second end face 55b are represented by the reference numeral 50B. In the third detection circuit 30, the plurality of MR elements 50A and the plurality of MR elements 50B are arranged so that the rows of the MR elements 50A arranged in a row and the rows of the MR elements 50B arranged in a row are alternately arranged in the direction parallel to the X direction. As shown in FIGS. 9 and 10, the plurality of MR elements 50A and the plurality of MR elements 50B need not overlap the plurality of yokes 55 when seen in the Z direction. In addition, as shown in FIG. 10, each of the plurality of MR elements 50A and the plurality of MR elements 50B is arranged near the bottom surface of each of the plurality of yokes 55.

Although not shown, the third detection circuit 30 further includes a plurality of first lower electrodes, a plurality of second lower electrodes, a plurality of first upper electrodes, and a plurality of second upper electrodes. In FIG. 9, the reference numeral 80 shows a wiring portion constituted of the plurality of first lower electrodes, the plurality of second lower electrodes, the plurality of first upper electrodes, and the plurality of second upper electrodes. The plurality of MR elements 50A are connected in series by the plurality of first lower electrodes and the plurality of first upper electrodes, similarly as the plurality of MR elements 50 in the first and second detection circuits 10, 20. The plurality of MR elements 50B are connected in series by the plurality of second lower electrodes and the plurality of second upper electrodes, similarly as the plurality of MR elements 50 in the first and second detection circuits 10, 20.

Each of the resistor sections R31 and R32 is constituted of a plurality of MR elements 50A. Each of the resistor sections R33 and R34 is constituted of a plurality of MR elements 50B. In either of the plurality of MR elements 50A and the plurality of MR elements 50B, the magnetization pinned layers 52 are magnetized in the direction parallel to the X direction.

In FIG. 7, graphics representing the resistor sections R31 to R34 are shown, and each of the graphics schematically shows one MR element 50A or 50B. In FIG. 7, the filled arrows indicate the magnetization directions of the magnetization pinned layers 52. In the example shown in FIG. 7, the magnetization pinned layers 52 in each of the resistor sections R31 and R34 are magnetized in the X direction. The magnetization pinned layers 52 in each of the resistor sections R32 and R33 are magnetized in the −X direction.

Next, at least one third detection signal generated by the third detection circuit 30 will be described with reference to FIG. 7. In FIG. 7, graphics representing the plurality of yokes 55 corresponding to the plurality of MR elements 50A of the resistor section R31 and the plurality of MR elements 50B of the resistor section R34 are shown, and each of the graphics schematically shows one yoke 55. Similarly, in FIG. 7, graphics representing the plurality of yokes 55 corresponding to the plurality of MR elements 50A of the resistor section R32 and the plurality of MR elements 50B of the resistor section R33 are shown, and each of the graphics schematically shows another one yoke 55.

In a state where no third magnetic field component MFz exists, and as a result, no output magnetic field component in a direction parallel to the X direction exists as well, the free layers 54 of the MR elements 50 are magnetized in a direction parallel to the Y direction. In the case where the third magnetic field component MFz in the Z direction exists, the output magnetic field components received by the MR elements 50A in the resistor sections R31 and R32 are in the X direction, and the output magnetic field components received by the MR elements 50B in the resistor sections R33 and R34 are in the −X direction. In this case, the magnetization direction of the free layers 54 of the MR elements 50A in the resistor sections R31 and R32 are inclined from the direction parallel to the Y direction to the X direction, and the magnetization direction of the free layers 54 of the MR elements 50B in the resistor sections R33 and R34 are inclined from the direction parallel to the Y direction to the −X direction. As a result, the resistance of each of the MR elements 50A in the resistor section R31 and the resistance of each of the MR elements 50B in the resistor section R33 decrease, and the resistance of each of the resistor sections R31 and R33 also decreases, in comparison with the state where no output magnetic field component exists. In addition, the resistance of each of the MR elements 50A in the resistor section R32 and the resistance of the plurality of MR elements 50B in the resistor section R34 increase, and the resistance of each of the resistor sections R32 and R34 also increases, in comparison with the state where no output magnetic field component exists.

In the case where the third magnetic field component MFz in the −Z direction exists, the direction of the output magnetic field component and the changes in the resistances of the resistor sections R31 to R34 become opposite from those in the above-described case where the third magnetic field component MFz in the Z direction exists.

The amount of change in the resistances of the MR elements 50 depends on the strength of the output magnetic field component that the MR elements 50 receive. As the strength of the output magnetic field component increases, the amount of increase or decrease in the resistances of the MR elements 50 increases. As the strength of the output magnetic field component decreases, the amount of increase or decrease in the resistances of the MR elements 50 decreases. The strength of the output magnetic field component depends on the strength of the third magnetic field component MFz.

Thus, changes in the direction and strength of the third magnetic field component MFz cause the resistances of the respective resistor sections R31 to R34 to change either so that the resistance of each of the resistor sections R31 and R33 increases and the resistance of each of the resistor sections R32 and R34 decreases, or so that the resistance of each of the resistor sections R31 and R33 decreases and the resistance of each of the resistor sections R32 and R34 increases. As a result, the potential of each of the output ports E31 and E32 shown in FIG. 7 changes.

The potential difference between the output port E31 and the output port E32 has a correspondence with the third magnetic field component MFz. The third detection circuit 30 generates a third detection signal S3 corresponding to the potential difference between the output port E31 and the output port E32. Note that the third detection circuit 30 may generate, instead of the third detection signal S3, two signals corresponding respectively to the potential of the output port E31 and the potential of the output port E32 as two third detection signals.

The magnetic field generator 70 will now be described with reference to FIGS. 2 and 3. As described above, the magnetic field generator 70 includes the first to third coils 71 to 73.

The first coil 71 is configured such that a component of the first additional magnetic field is applied to the first detection circuit 10, the component being a component in a direction parallel to the X direction. In the description below, simply referring to as the first additional magnetic field indicates the component in the direction parallel to the X direction of the first additional magnetic field, which is applied to the first detection circuit 10. The driving section 43 controls the direction and magnitude of the current flowing through the first coil 71, to thereby control the direction and strength of the first additional magnetic field. In the example embodiment, the first coil 71 includes, as an input/output end of the current flowing through the first coil 71, a first end portion 71a and a second end portion 71b. The first and second end portions 71a and 71b are connected to the driving section 43 of the processor 2. When the current is flowed in the direction from the first end portion 71a toward the second end portion 71b, the first additional magnetic field in the X direction is applied to the first detection circuit 10. On the other hand, when the current is flowed in the direction from the second end portion 71b toward the first end portion 71a, the first additional magnetic field in the −X direction is applied to the first detection circuit 10. The storage section 44 of the processor 2 may store the data indicating the correspondence between the current flowing through the first coil 71 and the first additional magnetic field.

The second coil 72 is configured such that a component of the second additional magnetic field is applied to the second detection circuit 20, the component being a component in a direction parallel to the Y direction. In the description below, simply referring to as the second additional magnetic field indicates the component in the direction parallel to the Y direction of the second additional magnetic field, which is applied to the second detection circuit 20. The driving section 43 controls the direction and magnitude of the current flowing through the second coil 72, to thereby control the direction and strength of the second additional magnetic field. In the example embodiment, the second coil 72 includes, as an input/output end of the current flowing through the second coil 72, a first end portion 72a and a second end portion 72b. The first and second end portions 72a and 72b are connected to the driving section 43 of the processor 2. When the current is flowed in the direction from the first end portion 72a toward the second end portion 72b, the second additional magnetic field in the Y direction is applied to the second detection circuit 20. On the other hand, when the current is flowed in the direction from the second end portion 72b toward the first end portion 72a, the second additional magnetic field in the −Y direction is applied to the second detection circuit 20. The storage section 44 of the processor 2 may store the data indicating the correspondence between the current flowing through the second coil 72 and the second additional magnetic field.

The third coil 73 is configured such that a component of the third additional magnetic field is applied to the third detection circuit 30, the component being a component in a direction parallel to the Z direction. In the description below, simply referring to as the third additional magnetic field indicates the component in the direction parallel to the Z direction of the third additional magnetic field, which is applied to the third detection circuit 30. The driving section 43 controls the direction and magnitude of the current flowing through the third coil 73, to thereby control the direction and strength of the third additional magnetic field. In the example embodiment, the third coil 73 includes, as an input/output end of the current flowing through the third coil 73, a first end portion 73a and a second end portion 73b. The first and second end portions 73a and 73b are connected to the driving section 43 of the processor 2. When the current is flowed in the direction from the first end portion 73a toward the second end portion 73b, the third additional magnetic field in the Z direction is applied to the third detection circuit 30. On the other hand, when the current is flowed in the direction from the second end portion 73b toward the first end portion 73a, the third additional magnetic field in the −Z direction is applied to the third detection circuit 30. The storage section 44 of the processor 2 may store the data indicating the correspondence between the current flowing through the third coil 73 and the third additional magnetic field.

Next, the processor 2 will be described. In magnetic sensors, offsets may occur in detection signals of the magnetic sensors due to disturbance magnetic fields, etc. The sensitivity of the magnetic sensors can change due to individual differences of the magnetic sensors and environments in which the magnetic sensors are used. The offsets and the change in the sensitivity may cause detection errors in the magnetic sensors. The magnetic sensors are therefore desirably capable of correcting the offsets and the sensitivity. The processor 2 is configured to perform detection value generation processing, sensitivity correction processing, offset correction processing using offset values, offset correction processing using the additional magnetic fields, and nonlinearity correction processing.

First, the detection value generation processing will be described. The detection value generation processing is processing for generating three detection values having correspondences respectively with the first to third magnetic field components MFx, MFy, and MFz. The computation section 41 of the processor 2 receives the first detection signal S1 output from the first detection circuit 10, the second detection signal S2 output from the second detection circuit 20, and the third detection signal S3 output from the third detection circuit 30. Each of the first to third detection signals S1 to S3 is converted from an analog signal to a digital signal by an analog-to-digital converter, not shown, to be input to the computation section 41.

As described above, the first detection signal S1 has the correspondence with the first magnetic field component MFx. FIG. 11 is a characteristic chart showing an example of a relationship between the first magnetic field component MFx and the first detection signal S1. In FIG. 11, the horizontal axis indicates the strength of the first magnetic field component MFx, and the vertical axis indicates the magnitude of the first detection signal S1. Note that, in FIG. 11, the strength of the first magnetic field component MFx is indicated by the value of a magnetic flux density corresponding to the strength of the first magnetic field component MFx. In the description below, the strength of the magnetic field or the magnetic field component is indicated by a value of the magnetic flux density corresponding to the strength of the magnetic field or the magnetic field component.

In addition, in FIG. 11, the strength of the first magnetic field component MFx when the strength of the first magnetic field component MFx is in the X direction is expressed by a positive value, and the strength of the first magnetic field component MFx when the strength of the first magnetic field component MFx is in the −X direction is expressed by a negative value. As shown in FIG. 11, the magnitude of the first detection signal S1 changes depending on the strength of the first magnetic field component MFx. The computation section 41 is configured to generate the first detection value having a correspondence with the first magnetic field component MFx, based on the first detection signal S1 at the time when the first magnetic field component MFx is applied to the first detection circuit 10.

Here, the definition of the sensitivity of the first detection circuit 10 will be described. The sensitivity of the first detection circuit 10 is a ratio of a change in the first detection signal S1 with respect to a change in the first magnetic field component MFx. The sensitivity of the first detection circuit 10 can be obtained based on the correspondence between the first magnetic field component MFx and the first detection signal S1 as shown in FIG. 11. The storage section 44 of the processor 2 may store the data indicating the correspondence between the first magnetic field component MFx and the first detection signal S1 and the data on the sensitivity of the first detection circuit 10. The data may be data acquired before shipment or use of the magnetic sensor device 100, by regarding the first additional magnetic field as the first magnetic field component MFx. The computation section 41 may generate the first detection value by computation including multiplying the first detection signal S1 by the sensitivity of the first detection circuit 10, for example.

In addition, as described above, the second detection signal S2 has the correspondence with the second magnetic field component MFy. Although not shown, the relationship between the second magnetic field component MFy and the second detection signal S2 is similar to that between the first magnetic field component MFx and the first detection signal S1. The computation section 41 generates the second detection value having a correspondence with the second magnetic field component MFy, based on the second detection signal S2 at the time when the second magnetic field component MFy is applied to the second detection circuit 20.

Similar to the sensitivity of the first detection circuit 10, the sensitivity of the second detection circuit 20 is a ratio of a change in the second detection signal S2 with respect to a change in the second magnetic field component MFy. The sensitivity of the second detection circuit 20 can be obtained based on the correspondence between the second magnetic field component MFy and the second detection signal S2. The storage section 44 of the processor 2 may store the data indicating the correspondence between the second magnetic field component MFy and the second detection signal S2 and the data on the sensitivity of the second detection circuit 20. The data may be data acquired before shipment or use of the magnetic sensor device 100, by regarding the second additional magnetic field as the second magnetic field component MFy. The computation section 41 may generate the second detection value by computation including multiplying the second detection signal S2 by the sensitivity of the second detection circuit 20, for example.

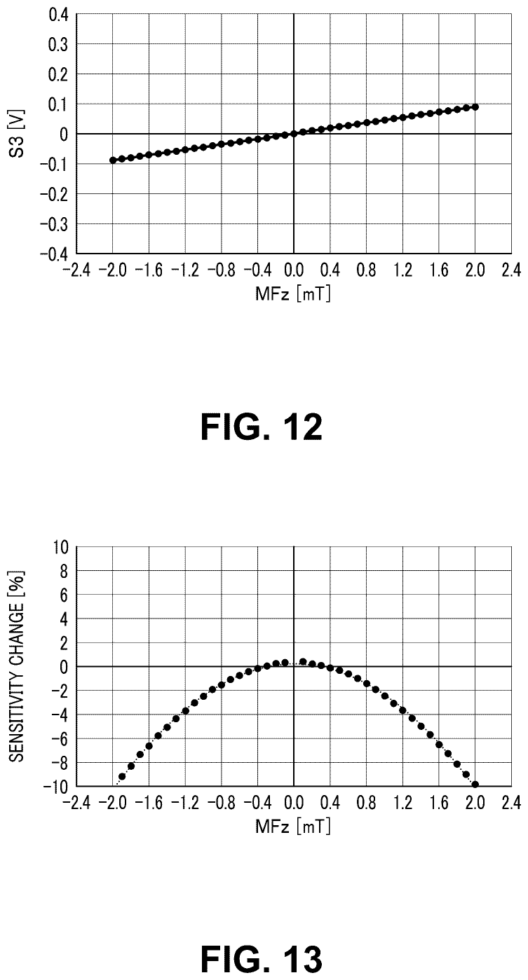

In addition, as described above, the third detection signal S3 has the correspondence with the third magnetic field component MFz. FIG. 12 is a characteristic chart showing an example of a relationship between the third magnetic field component MFz and the third detection signal S3. In FIG. 12, the horizontal axis indicates the strength of the third magnetic field component MFz, and the vertical axis indicates the magnitude of the third detection signal S3. Note that, in FIG. 12, the strength of the third magnetic field component MFz when the strength of the third magnetic field component MFz is in the Z direction is expressed by a positive value, and the strength of the third magnetic field component MFz when the strength of the third magnetic field component MFz is in the −Z direction is expressed by a negative value. As shown in FIG. 12, the magnitude of the third detection signal S3 changes depending on the strength of the third magnetic field component MFz. The computation section 41 generates the third detection value having a correspondence with the third magnetic field component MFz, based on the third detection signal S3 at the time when the target magnetic field is applied to the magnetic sensor 1.

Similar to the sensitivity of the first detection circuit 10, the sensitivity of the third detection circuit 30 is a ratio of a change in the third detection signal S3 with respect to a change in the third magnetic field component MFz. The sensitivity of the third detection circuit 30 can be obtained based on the correspondence between the third magnetic field component MFz and the third detection signal S3 shown in FIG. 12. Note that, as understood from FIG. 11 and FIG. 12, in the example embodiment, the sensitivity of the third detection circuit 30 is smaller than that of the first detection circuit 10. The storage section 44 of the processor 2 may store the data indicating the correspondence between the third magnetic field component MFz and the third detection signal S3 and the data on the sensitivity of the third detection circuit 30. The data may be data acquired before shipment or use of the magnetic sensor device 100, by regarding the third additional magnetic field as the third magnetic field component MFz. The computation section 41 may generate the third detection value by computation including multiplying the third detection signal S3 by the sensitivity of the third detection circuit 30, for example.

The computation section 41 is configured to output the generated first to third detection values to the outside of the magnetic sensor device 100.

Next, the sensitivity correction processing will be described. The sensitivity correction processing is processing for correcting the sensitivity of each of the first to third detection circuits 10, 20, and 30. First, the processing for correcting the sensitivity of the first detection circuit 10 will be described. The control section 42 of the processor 2 controls the first coil 71 of the magnetic field generator 70 by the driving section 43 so that the first additional magnetic field is generated, and the first additional magnetic field is changed. The control section 42 generates data in which the first detection signal S1 and the strength of the first additional magnetic field, i.e., the strength of the first magnetic field component MFx, when the first additional magnetic field is thus changed, are associated with each other. Note that the strength of the first magnetic field component MFx can be specified based on the magnitude of the current flowing through the first coil 71. Then, the control section 42 causes the storage section 44 of the processor 2 to store the data thus generated as the data indicating the correspondence between the first magnetic field component MFx and the first detection signal S1. In addition, the control section 42 calculates the sensitivity of the first detection circuit 10 based on the data indicating the correspondence between the first magnetic field component MFx and the first detection signal S1, to update the data on the sensitivity of the first detection circuit 10 stored by the storage section 44.

Next, the processing for correcting the sensitivity of the second detection circuit 20 will be described. The control section 42 of the processor 2 controls the second coil 72 of the magnetic field generator 70 by the driving section 43 so that the second additional magnetic field is generated, and the second additional magnetic field is changed. The control section 42 generates data in which the second detection signal S2 and the strength of the second additional magnetic field, i.e., the strength of the second magnetic field component MFy, when the second additional magnetic field is thus changed, are associated with each other. Note that the strength of the second magnetic field component MFy can be specified based on the magnitude of the current flowing through the second coil 72. Then, the control section 42 causes the storage section 44 of the processor 2 to store the data thus generated as the data indicating the correspondence between the second magnetic field component MFy and the second detection signal S2. In addition, the control section 42 calculates the sensitivity of the second detection circuit 20 based on the data indicating the correspondence between the second magnetic field component MFy and the second detection signal S2, to update the data on the sensitivity of the second detection circuit 20 stored by the storage section 44.

Next, the processing for correcting the sensitivity of the third detection circuit 30 will be described. The control section 42 of the processor 2 controls the third coil 73 of the magnetic field generator 70 by the driving section 43 so that the third additional magnetic field is generated, and the third additional magnetic field is changed. The control section 42 generates data in which the third detection signal S3 and the strength of the third additional magnetic field, when the third additional magnetic field is thus changed, are associated with each other. Note that the strength of the third additional magnetic field can be specified based on the magnitude of the current flowing through the third coil 73. Then, the control section 42 causes the storage section 44 of the processor 2 to store the data thus generated as the data indicating the correspondence between the third additional magnetic field and the third detection signal S3. In addition, the control section 42 calculates the sensitivity of the third detection circuit 30 based on the data indicating the correspondence between the third additional magnetic field and the third detection signal S3, to update the data on the sensitivity of the third detection circuit 30 stored by the storage section 44.

Note that in the case where the alternating magnetic field is used as each of the first to third additional magnetic fields, an error component having the frequency equal to or lower than the frequency of the alternating magnetic field can be removed. Thereby, the sensitivity of each of the first to third detection circuits 10, 20, and 30 can be corrected more accurately.

Next, offset correction processing using offset values will be described. The offset correction processing is processing for correcting the offset of each of the first to third detection signals S1 to S3. The storage section 44 of the processor 2 may be configured to store a first offset value which is an offset value of the first detection signal S1, a second offset value which is an offset value of the second detection signal S2, and a third offset value which is an offset value of the third detection signal S3. Each of the first to third offset values is updated by update processing to be described later.

The control section 42 of the processor 2 may control the computation section 41 so as to correct the offsets of the first to third detection signals S1 to S3 by using the first to third offset values. The computation section 41, for example, corrects the first detection signal S1 by subtracting the first offset value from the first detection signal S1. Similarly, the computation section 41, for example, corrects the second detection signal S2 by subtracting the second offset value from the second detection signal S2, and corrects the third detection signal S3 by subtracting the third offset value from the third detection signal S3.

Next, offset correction processing using additional magnetic fields will be described. Herein, description will be made by taking the third detection circuit 30 as an example. First, parameters related to the sensitivity of the third detection circuit 30 will be described. One of the parameters related to the sensitivity includes a sensitivity change. The sensitivity change is a parameter indicating an amount of change, i.e., how much the sensitivity when the strength of the third magnetic field component MFz is within a predetermined range is changed from the sensitivity when the strength of the third magnetic field component MFz is within a reference range. The sensitivity when the strength of the third magnetic field component MFz is within the reference range may be the sensitivity when the strength of the third magnetic field component MFz is within the range including 0, for example.

FIG. 13 is a characteristic chart showing an example of a relationship between the third magnetic field component MFz and the sensitivity change. In FIG. 13, the horizontal axis indicates the third magnetic field component MFz, and the vertical axis indicates the sensitivity change. As shown in FIG. 13, the absolute value of the sensitivity change is at its minimum, when the strength of the third magnetic field component MFz is within the predetermined range including 0. In addition, the absolute value of the sensitivity change increases as the strength of the third magnetic field component MFz becomes smaller than 0 and also increases as the strength of the third magnetic field component MFz becomes larger than 0. When the sensitivity of the third detection circuit 30 is a positive value, the sensitivity of the third detection circuit 30 is at its maximum when the strength of the third magnetic field component MFz is within the predetermined range including 0. FIG. 13 shows that the sensitivity of the third detection circuit 30 becomes small as the sensitivity of the third detection circuit 30 is away from 0. The storage section 44 of the processor 2 may store the data indicating the correspondence between the third magnetic field component MFz and the sensitivity of the third detection circuit 30, or in addition to or instead of the data, may store the data indicating the correspondence between the third magnetic field component MFz and the sensitivity change shown in FIG. 13. These data may be data acquired before shipment or use of the magnetic sensor device 100, by using the third additional magnetic field.

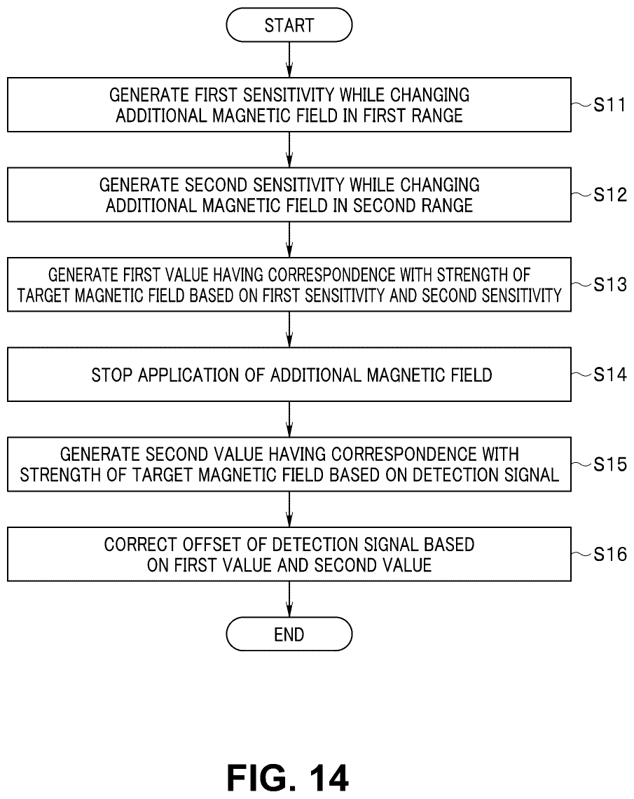

The processor 2 corrects the offset of the third detection signal S3 using the third additional magnetic field, by utilizing the characteristics of the sensitivity shown in FIG. 13. Hereinafter, with reference to FIG. 14, an overview of the correction method for correcting the offset of the third detection signal S3 using the third additional magnetic field. Description on the following correction method includes the description on the correction method according to the example embodiment. In the correction method, the control section 42 of the processor 2 first controls the driving section 43 so that the third additional magnetic field is applied to the third detection circuit 30, and controls the computation section 41 to generate first sensitivity, which is the sensitivity of the third detection circuit 30 in a first range, while controlling the driving section 43 so that the strength of the third additional magnetic field changes in the first range (step S11).

Next, the control section 42 controls the computation section 41 to generate second sensitivity, which is the sensitivity of the third detection circuit 30 in a second range, while controlling the driving section 43 so that the strength of the third additional magnetic field changes in the second range (step S12).

Next, the control section 42 controls the computation section 41 to generate a first value having a correspondence with the strength of the third magnetic field component MFz based on the first sensitivity and the second sensitivity (step S13).

Next, the control section 42 controls the driving section 43 so that the application of the third additional magnetic field to the third detection circuit 30 is stopped (step S14). Next, the control section 42 controls the computation section 41 to generate a second value having a correspondence with the strength of the third magnetic field component MFz based on the third detection signal S3 (step S15).

Next, the control section 42 controls the computation section 41 to correct the offset of the third detection signal S3 based on the first value and the second value (step S16). The step S16 includes: a first step in which the control section 42 controls the computation section 41 to generate an offset value; a second step in which the control section 42 executes the update processing for updating the offset value stored in the storage section 44 with the generated offset value; and a third step in which the control section 42 corrects the offset of the third detection signal S3 using the updated offset value.

The above-described series of steps are executed by the processor 2. Thus, it can be said that the processor 2 is a correction device that executes the offset correction processing using the additional magnetic field. Note that the step S15 may be performed before the step S11.

In addition, among the above-described series of steps, the series of steps from the step S11 to the first step in the step S16 is also a generation method for generating the offset value of the third detection signal S3. Among the above-described series of steps, the series of steps from the step S11 to the second step in the step S16 is also an update method for updating the offset value of the third detection signal S3.

Next, the correction method will be further described in detail by showing specific examples of the first range and the second range. Here, it is supposed that the sensitivity of the third detection circuit 30 is a positive value. In addition, when X is any positive number, the first range is a range in which the strength of the third additional magnetic field is from −XmT to 0 mT, and the second range is a range in which the strength of the third additional magnetic field is from 0 mT to XmT. Note that X may be small from the viewpoint of improving the accuracy of determination. The first sensitivity of the third detection circuit 30 is generated by changing the strength of the third additional magnetic field in the range from −XmT to 0 mT. The second sensitivity of the third detection circuit 30 is generated by changing the strength of the third additional magnetic field in the range from 0 mT to XmT. When the strength of the third magnetic field component MFz detected by the third detection circuit 30 is a positive value, the first sensitivity is larger than the second sensitivity, and when the strength of the third magnetic field component MFz detected by the third detection circuit 30 is a negative value, the first sensitivity is smaller than the second sensitivity. When the strength of the third magnetic field component MFz detected by the third detection circuit 30 is 0, the first sensitivity is equal to the second sensitivity. Thus, the strength of the third magnetic field component MFz can be determined by using the sensitivity characteristics shown in FIG. 13.

Note that, in the case where the sensitivity of the third detection circuit 30 is a negative value, when the strength of the third magnetic field component MFz is a negative value, the first sensitivity is larger than the second sensitivity, and when the strength of the third magnetic field component MFz is a positive value, the first sensitivity is smaller than the second sensitivity. In addition, similarly as in the case where the sensitivity of the third detection circuit 30 is a positive value, in the case where the strength of the third magnetic field component MFz is 0, the first sensitivity is equal to the second sensitivity.

When the first sensitivity is equal to the second sensitivity, the first value, which is generated based on the first sensitivity and the second sensitivity and represents the strength of the third magnetic field component MFz, may be 0. In this case, since the strength of the third magnetic field component MFz is 0, when no offset exists in the third detection signal S3, the second value, which is generated based on the third detection signal S3 and represents the strength of the third magnetic field component MFz, is also 0. However, in the case where an offset exists in the third detection signal S3, the second value is a value other than 0 (for example, 1.2 mT). In this case, the magnitude of the third detection signal S3 corresponding to the second value is the offset value. The magnitude of the third detection signal S3 corresponding to the second value can be specified with reference to, for example, the data stored in the storage section 44 and indicating the correspondence between the third magnetic field component MFz and the third detection signal S3.

In the above description, the strength of the third magnetic field component MFz is determined as the positive value or the negative value, depending on the magnitude relationship between the first sensitivity and the second sensitivity. The determination substantially corresponds to the determination on whether the direction of the third magnetic field component MFz is the Z direction or the −Z direction.

The offset correction processing using the third additional magnetic field is executed before or during the use of the magnetic sensor device 100.

Note that the above-described first range and the second range are one example. Various changes are possible in the first range and the second range, as long as the strength of the third magnetic field component MFz can be determined. For example, the boundary between the first range and the second range does not have to be 0. Alternatively, the first range and the second range do not have to be continuous.

The offset correction processing using the additional magnetic field has been explained so far, using the third detection circuit 30 as an example. The foregoing description also applies to the first detection circuit 10 and the second detection circuit 20.

Next, the nonlinearity correction processing will be described. Herein, description will be made by taking the third detection circuit 30 as an example. A definition of the linearity of the third detection signal S3 will be described first. The linearity is defined by using the characteristic curve (see FIG. 12) showing the correspondence between the strength of the third magnetic field component MFz and the magnitude of the third detection signal S3, and an approximate straight line of the characteristic curve. In other words, the linearity is a value obtained, in each of the strengths of a plurality of the third magnetic field components MFz, by dividing a residue between a value on the approximate straight line and a value on the characteristic curve by a size of the variable range of the third detection signal S3. It can be said that the smaller the value of the linearity, the better the linearity.

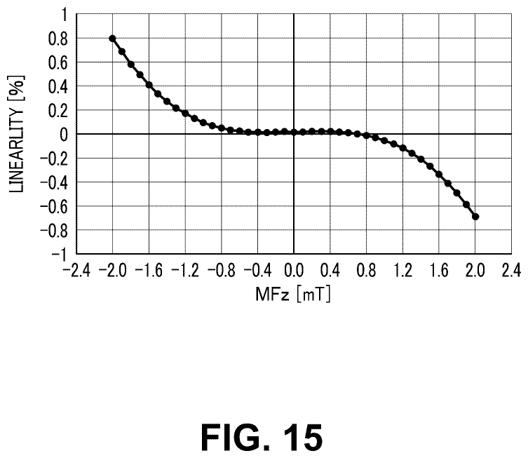

FIG. 15 is a characteristic chart showing the linearity of the third detection signal S3. In FIG. 15, the horizontal axis indicates the strength of the third magnetic field component MFz, and the vertical axis indicates the linearity of the third detection signal S3. As shown in FIG. 15, the absolute value of the linearity increases, as the absolute value of the strength of the third magnetic field component MFz increases. The storage section 44 of the processor 2 may store the data indicating the correspondence between the strength of the third magnetic field component MFz and the linearity of the third detection signal S3. The data may be data acquired before shipment or use of the magnetic sensor device 100, by regarding the third additional magnetic field as the third magnetic field component MFz.

The storage section 44 may further store a correction coefficient for correcting the nonlinearity of the change in the third detection signal S3 with respect to the change in the strength of the third magnetic field component MFz. As shown in FIG. 15, the linearity changes according to the strength of the third magnetic field component MFz, also the correction coefficient changes according to the strength of the third magnetic field component MFz. The correction coefficient may be data acquired before shipment or use of the magnetic sensor device 100, by regarding the third additional magnetic field as the third magnetic field component MFz.

The control section 42 of the processor 2 may control the computation section 41 to correct the third detection signal using the correction coefficient so that the characteristic curve approaches the approximate straight line.

Up to this point, description has been made on the nonlinearity correction processing by using the third detection circuit 30 as an example. The foregoing description also applies to the first detection circuit 10 and the second detection circuit 20.

When the target magnetic field is an alternating magnetic field, each of the first to third detection signals S1 to S3 is distorted due to the alternating magnetic field. To deal with the above, the nonlinearity correction processing is performed on each of the first to third detection signals S1 to S3, to thereby be capable of correcting the distortion of each of the first to third detection signals S1 to S3. With such processing, a detection error of each of the first to third detection circuits 10, 20, and 30 can be reduced.

The operation and effects of the magnetic sensor device 100, the magnetic sensor system 200, and the correction method according to the example embodiment will now be described. In the example embodiment, as described above, the first sensitivity, which is the sensitivity of the third detection circuit 30 when the strength of the third additional magnetic field is changed in the first range, and the second sensitivity, which is the sensitivity of the third detection circuit 30 when the strength of the third additional magnetic field is changed in the second range, are generated, and based on the third detection signal S3, the first sensitivity, and the second sensitivity, the third detection value having the correspondence with the strength of the third magnetic field component MFz is generated. Specifically, the third detection value is generated using the third detection signal S3 corrected based on the first sensitivity and the second sensitivity.

In the example embodiment, in particular, the offset value is generated based on the first sensitivity and the second sensitivity, and the offset of the third detection signal S3 is corrected using the offset value. The offset of the third detection signal S3 can also be corrected by using center coordinates of a virtual sphere, as will be described in the second example embodiment. However, in order to enhance the calculation accuracy of the center coordinates of the virtual sphere, data from many measurement points is required, which increases the load required for the calculation.

In contrast, in the example embodiment, the offset of the third detection signal S3 can be corrected by a relatively simple method of using the first sensitivity and the second sensitivity. In addition, in order to calculate the center coordinates of the virtual sphere, predetermined operation of moving the magnetic sensor device 100 is required for acquiring a plurality of measurement points. In contrast, the example embodiment does not require the predetermined operation as described above. According to the example embodiment, the detection error of the third detection circuit 30 due to the offset of the third detection signal S3 can thus be reduced by the simple method.

In addition, in the example embodiment, the third detection circuit 30 includes the plurality of yokes 55. If the plurality of yokes 55 are magnetized in a predetermined direction due to a disturbance magnetic field or the like, an offset may occur in the third detection signal S3. In contrast, according to the example embodiment, the offset of the third detection signal S3 can be corrected by the simple method as described above.

Note that when the plurality of yokes 55 are magnetized in the predetermined direction, the sensitivity of the third detection circuit 30 may deviate. In contrast, according to the example embodiment, the sensitivity of the third detection circuit 30 can be corrected using the third additional magnetic field.

The foregoing description on the third detection circuit 30 is basically applied also to the first detection circuit 10. In the example embodiment, the first sensitivity, which is the sensitivity of the first detection circuit 10 when the strength of the first additional magnetic field is changed in the first range, and the second sensitivity, which is the sensitivity of the first detection circuit 10 when the strength of the first additional magnetic field is changed in the second range, are generated, and based on the first detection signal S1, the first sensitivity, and the second sensitivity, the first detection value having the correspondence with the strength of the first magnetic field component MFx is generated. Specifically, the first detection value is generated using the first detection signal S1 corrected based on the first sensitivity and the second sensitivity. According to the example embodiment, the detection error of the first detection circuit 10 due to the offset of the first detection signal S1 can be reduced by the simple method.

The foregoing description on the third detection circuit 30 is basically applied also to the second detection circuit 20. In the example embodiment, the first sensitivity, which is the sensitivity of the second detection circuit 20 when the strength of the second additional magnetic field is changed in the first range, and the second sensitivity, which is the sensitivity of the second detection circuit 20 when the strength of the second additional magnetic field is changed in the second range, are generated, and based on the second detection signal S2, the first sensitivity, and the second sensitivity, the second detection value having the correspondence with the strength of the second magnetic field component MFy is generated. Specifically, the second detection value is generated using the second detection signal S2 corrected based on the first sensitivity and the second sensitivity. According to the example embodiment, the detection error of the second detection circuit 20 due to the offset of the second detection signal S2 can be reduced by the simple method.

### Second Example Embodiment

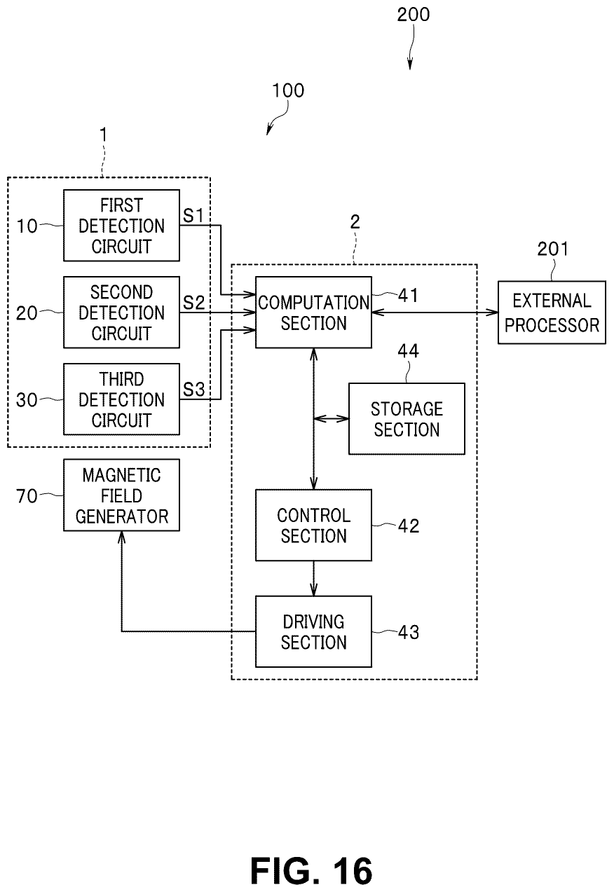

Next, a second example embodiment of the technology will be described. First, a configuration of a magnetic sensor system 200 according to the example embodiment will be briefly described with reference to FIG. 16. The magnetic sensor system 200 includes a magnetic sensor device 100 according to the example embodiment, and an external processor 201 as what is called a host processor. The configuration of the magnetic sensor device 100 according to the example embodiment is similar to that of the magnetic sensor device 100 according to the first example embodiment. In the example embodiment, in particular, the target magnetic field of the magnetic sensor 1 of the magnetic sensor device 100 is geomagnetism.

The hardware that constitutes the external processor 201 is different from that constituting the processor 2. For example, the external processor 201 is constructed of a microcomputer.

Next, the operation of the external processor 201 will be described. The external processor 201 is configured to receive the first to third detection signals S1 to S3 from the processor 2. Here, in the reference coordinate system described in the first example embodiment, coordinates (S1, S2, S3) representing a set of values of the first to third detection signals S1, S2, and S3 in a certain timing are taken as a measurement point. At the time of using the magnetic sensor device 100, if a plurality of measurement points in a plurality of timings are obtained and the plurality of measurement points are plotted on the reference coordinate system, the distribution of the plurality of measurement points can be approximated by a spherical surface. In the example embodiment, the spherical surface approximating the distribution of the plurality of measurement points will be referred to as an approximate spherical surface. The plurality of measurement points are distributed over the approximate spherical surface or near the approximate spherical surface.

The external processor 201 generates center coordinates and a radius of a virtual sphere having the approximate spherical surface by a calculation using the first to third detection signals S1 to S3. The center coordinates and the radius of the virtual sphere may be determined by, for example, determining an approximate spherical surface including four measurement points by using the four measurement points and an equation of the spherical surface. Alternatively, the center coordinates and the radius of the virtual sphere may be obtained by determining an approximate spherical surface closest to five or more measurement points by using the five or more measurement points, the equation of the spherical surface, and the least squares method.

As described above, the plurality of measurement points are distributed over the approximate spherical surface or near the approximate spherical surface. If no offset occurs, the center coordinates of the virtual sphere during the use of the magnetic sensor device 100 coincide or substantially coincide with the center coordinates of the virtual sphere immediately after the start of use of the magnetic sensor device 100. However, if an offset occurs in each of the first to third detection signals S1 to S3 due to the disturbance other than the geomagnetism, the center coordinates of the virtual sphere deviates from the initial value of the center coordinates of the virtual sphere (e.g., the center coordinates of the virtual sphere at the time of shipment).

The processor 2 of the magnetic sensor device 100 uses the data on the center coordinates of the virtual sphere, to correct the offset of each of the first to third detection signals S1 to S3 so that the center coordinates of the virtual sphere during the use of the magnetic sensor device 100 coincides with the initial value of the center coordinates of the virtual sphere. Here, the center coordinates of the virtual sphere will be expressed as (cx, cy, cz). The offset of the first detection signal S1 can be corrected by subtracting cx from the first detection signal S1, for example. Similarly, the offset of the second detection signal S2 can be corrected by subtracting cy from the second detection signal S2, for example. Similarly, the offset of the third detection signal S3 can be corrected by subtracting cz from the third detection signal S3, for example. The external processor 201 substantially calculates the offsets due to the disturbance other than the geomagnetism. The offsets to be corrected by the processor 2 may be the ones caused due to the disturbance other than the geomagnetism. The offsets caused due to the disturbance other than the geomagnetism include an offset due to a disturbance magnetic field, an offset due to the MR elements 50.

In the example embodiment, the data on the center coordinates of the virtual sphere, which has been generated by the external processor 201, is input to the processor 2. The storage section 44 of the processor 2 updates the offset values of the first to third detection signals S1 to S3 by using the data on the center coordinates of the virtual sphere.

Next, operation of the processor 2 of the example embodiment will be described. Similarly as in the first example embodiment, the processor 2 generates the first sensitivity and the second sensitivity by using the first to third additional magnetic fields, and thereby the magnetic field applied to the first to third detection circuits 10, 20, and 30 can be detected. In this case, the offsets of the first to third detection signals S1 to S3 can be detected by comparing the strength of the component in a predetermined direction of the magnetic field applied to the first to third detection circuits 10, 20, and 30, which has been detected based on the first sensitivity and the second sensitivity, and the strength of the component in the predetermined direction of the magnetic field applied to the first to third detection circuits 10, 20, and 30, which has been detected without using the first to third additional magnetic fields.

When detecting the offsets of the first to third detection signals S1 to S3, the processor 2 may output a command signal to the external processor 201 so as to generate the center coordinates and radius of the virtual sphere having the approximate spherical surface.

Next, operation and effects of the magnetic sensor system 200 according to the example embodiment will now be described. According to the example embodiment, the processor 2 can easily detect the offsets of the first to third detection signals S1 to S3. Thus, according to the example embodiment, the load on the external processor 201 can be reduced.

Note that the technology is not limited to the foregoing example embodiments, and various modifications may be made thereto. For example, the magnetic sensor 1 of the example embodiment may not include any one of the first to third detection circuits 10, 20, and 30.

In addition, the first coil 71 and the second coil 72 may be arranged so as to overlap with both the first and second detection circuits 10 and 20. Furthermore, the first to third coils 71 to 73 may be arranged above the magnetic sensor 1.

In addition, the target magnetic field may be an alternating magnetic field. In this case, the first to third detection circuits 10, 20, and 30 of the magnetic sensor 1 are connected to the processor 2 using an AC coupling capacitor. In this case, the processor 2 uses the alternating magnetic field as the additional magnetic fields, to generate the first sensitivity and the second sensitivity, to thereby be capable of detecting a static magnetic field applied to the magnetic sensor 1.

As described above, a magnetic sensor device according to one embodiment of the technology includes: a magnetic sensor configured to detect a component of a magnetic field and generate a detection signal; a magnetic field generator configured to generate an additional magnetic field to measure sensitivity of the magnetic sensor in a direction of the component of the magnetic field; and a processor. The processor is configured to: receive the detection signal; generate first sensitivity that indicates the sensitivity of the magnetic sensor when a strength of the additional magnetic field is changed in a first range, generate second sensitivity that indicates the sensitivity of the magnetic sensor when the strength of the additional magnetic field is changed in a second range, and generate a detection value corresponding to the component of the magnetic field, based on the detection signal, the first sensitivity, and the second sensitivity.

In the magnetic sensor device according to one embodiment of the technology, the sensitivity of the magnetic sensor may change according to a strength of the component of the magnetic field applied to the magnetic sensor.

In the magnetic sensor device according to one embodiment of the technology, when the first sensitivity and the second sensitivity are equal to each other, the processor may determine that a strength of the component of the magnetic field applied to the magnetic sensor is zero.

In the magnetic sensor device according to one embodiment of the technology, the processor may determine, by referring to the first sensitivity and the second sensitivity, whether a direction of the component of the magnetic field applied to the magnetic sensor is a first direction or a second direction opposite to the first direction.

In the magnetic sensor device according to one embodiment of the technology, the processor may be further configured to store data indicating a correspondence between a strength of the component of the magnetic field applied to the magnetic sensor and the sensitivity of the magnetic sensor, and refer to the data stored when generating the detection value.

In the magnetic sensor device according to one embodiment of the technology, the magnetic field generator may include a coil. The strength of the additional magnetic field may change depending on a magnitude of a current flowing through the coil. The processor may be further configured to store data indicating a correspondence between the magnitude of the current flowing through the coil and the strength of the additional magnetic field.

In the magnetic sensor device according to one embodiment of the technology, the magnetic field generator may be configured to generate an alternating magnetic field as the additional magnetic field.

In the magnetic sensor device according to one embodiment of the technology, the processor may correct the detection signal based on the first sensitivity and the second sensitivity. The processor may be further configured to store an offset value of the detection signal. The processor may correct the detection signal using the offset value. The processor may be configured to: generate a first value representing a strength of the component of the magnetic field applied to the magnetic sensor, based on the first sensitivity and the second sensitivity in a particular timing; generate a second value representing the strength of the component of the magnetic field applied to the magnetic sensor based on the detection signal in the particular timing; and update the offset value based on the first value and the second value. The particular timing may be before use of the magnetic sensor device. Alternatively, the particular timing may be during the use of the magnetic sensor device.

In addition, in the magnetic sensor device according to one embodiment of the technology, the processor may be further configured to store a correction coefficient for correcting a nonlinearity of a change in the detection signal with respect to a change in a strength of the component of the magnetic field applied to the magnetic sensor, and correct the detection signal by referring to the correction coefficient. The correction coefficient may vary depending on the strength of the component of the magnetic field applied to the magnetic sensor. The processor may generate the correction coefficient by changing the strength of the additional magnetic field.

In the magnetic sensor device according to one embodiment of the technology, the magnetic sensor may include a magnetic detection element, and a yoke formed of a soft magnetic body. The yoke may be configured to generate an output magnetic field component that is to be detected by the magnetic detection element, based on the component of the magnetic field applied to the magnetic sensor.

In the magnetic sensor device according to one embodiment of the technology, the magnetic sensor may include a magnetoresistive element.

In the magnetic sensor device according to one embodiment of the technology, each of the magnetic sensor and the processor may include a top surface and a bottom surface that face directions opposite to each other. The magnetic sensor may be mounted to the processor in such an orientation that the bottom surface of the magnetic sensor faces the top surface of the processor. The magnetic field generator may include a coil. The coil may be disposed between the top surface of the magnetic sensor and the bottom surface of the processor.

A magnetic sensor system according to one embodiment of the technology includes the magnetic sensor device according to one embodiment of the technology and an external processor. The detection signal includes a first signal, a second signal, and a third signal that have correspondences with components in three mutually different directions of the magnetic field at a reference position. The external processor generates data on center coordinates of a virtual sphere having a spherical surface in an orthogonal coordinate system defined by three axes indicating values of the first signal, the second signal, and the third signal. The spherical surface approximates a distribution of a plurality of measurement points in a plurality of timings, each of the plurality of measurement points represents coordinates in the orthogonal coordinate system corresponding to a set of values of the first signal, the second signal, and the third signal at a certain timing. The processor of the magnetic sensor device corrects an offset of each of the first signal, the second signal, and the third signal by referring to the data on the center coordinates.

In the magnetic sensor system according to one embodiment of the technology, the offset corrected by the processor of the magnetic sensor device may include an offset caused due to a disturbance other than geomagnetism.

A correction method according to one embodiment of the technology is a correction method for a magnetic sensor configured to detect a magnetic field. The correction method according to one embodiment of the technology includes: applying an additional magnetic field to the magnetic sensor, the additional magnetic field being used to measure sensitivity of the magnetic sensor; generating first sensitivity that indicates the sensitivity of the magnetic sensor while changing a strength of the additional magnetic field in a first range; generating second sensitivity that indicates the sensitivity of the magnetic sensor while changing the strength of the additional magnetic field in a second range; generating a first value indicating a correspondence with a strength of a component of the magnetic field applied to the magnetic sensor, based on the first sensitivity and the second sensitivity; generating a second value indicating a correspondence with the strength of the component of the magnetic field applied to the magnetic sensor based on a detection signal of the magnetic sensor; and correcting an offset of the detection signal based on the first value and the second value. The magnetic sensor device and the magnetic sensor system of the technology generate the first sensitivity that indicates the sensitivity of the magnetic sensor when the strength of the additional magnetic field is changed in the first range, generate the second sensitivity that indicates the sensitivity of the magnetic sensor when the strength of the additional magnetic field is changed in the second range, and generate the detection value corresponding to the component of the magnetic field based on the detection signal, the first sensitivity, and the second sensitivity. The correction method of the technology includes: generating the first value indicating the correspondence with the strength of the component of the magnetic field applied to the magnetic sensor, based on the first sensitivity and the second sensitivity; generating the second value indicating the correspondence with the strength of the component of the magnetic field applied to the magnetic sensor based on the detection signal; and correcting the offset of the detection signal based on the first value and the second value. According to the technology, the first sensitivity and the second sensitivity are used, to thereby enable a detection error of the magnetic sensor to be reduced with a simple method.

Obviously, many modifications and variations of the technology are possible in the light of the above teachings. Thus, it is to be understood that, within the scope of the appended claims and equivalents thereof, the technology may be practiced in other embodiments than the foregoing example embodiments.

1. A magnetic sensor device comprising:
a magnetic sensor configured to detect a component of a magnetic field and generate a detection signal;
a magnetic field generator configured to generate an additional magnetic field to measure sensitivity of the magnetic sensor in a direction of the component of the magnetic field; and
a processor configured to:
receive the detection signal;
generate first sensitivity that indicates the sensitivity of the magnetic sensor when a strength of the additional magnetic field is changed in a first range;
generate second sensitivity that indicates the sensitivity of the magnetic sensor when the strength of the additional magnetic field is changed in a second range; and
generate a detection value corresponding to the component of the magnetic field, based on the detection signal, the first sensitivity, and the second sensitivity.

2. The magnetic sensor device according to claim 1, wherein the sensitivity of the magnetic sensor changes according to a strength of the component of the magnetic field applied to the magnetic sensor.

3. The magnetic sensor device according to claim 1, wherein, when the first sensitivity and the second sensitivity are equal to each other, the processor determines that a strength of the component of the magnetic field applied to the magnetic sensor is zero.

4. The magnetic sensor device according to claim 1, wherein
the processor determines, by referring to the first sensitivity and the second sensitivity, whether a direction of the component of the magnetic field applied to the magnetic sensor is a first direction or a second direction opposite to the first direction.

5. The magnetic sensor device according to claim 1, wherein the processor is further configured to
store data indicating a correspondence between a strength of the component of the magnetic field applied to the magnetic sensor and the sensitivity of the magnetic sensor, and
refer to the data stored when generating the detection value.

6. The magnetic sensor device according to claim 1, wherein the magnetic field generator includes a coil, and the strength of the additional magnetic field changes depending on a magnitude of a current flowing through the coil.

7. The magnetic sensor device according to claim 6, wherein the processor is further configured to store data indicating a correspondence between the magnitude of the current flowing through the coil and the strength of the additional magnetic field.

8. The magnetic sensor device according to claim 1, wherein the magnetic field generator is configured to generate an alternating magnetic field as the additional magnetic field.

9. The magnetic sensor device according to claim 1, wherein the processor corrects the detection signal based on the first sensitivity and the second sensitivity.

10. The magnetic sensor device according to claim 9, wherein
the processor is further configured to store an offset value of the detection signal, and
the processor corrects the detection signal using the offset value.

11. The magnetic sensor device according to claim 10, wherein
the processor is configured to:
generate a first value representing a strength of the component of the magnetic field applied to the magnetic sensor, based on the first sensitivity and the second sensitivity in a particular timing;
generate a second value representing a strength of the component of the magnetic field applied to the magnetic sensor based on the detection signal in the particular timing; and
update the offset value based on the first value and the second value.

12. The magnetic sensor device according to claim 11, wherein the particular timing is before a use of the magnetic sensor device.

13. The magnetic sensor device according to claim 11, wherein the particular timing is during a use of the magnetic sensor device.

14. The magnetic sensor device according to claim 1, wherein
the processor is further configured to
store a correction coefficient for correcting a nonlinearity of a change in the detection signal with respect to a change in a strength of the component of the magnetic field applied to the magnetic sensor, and
correct the detection signal by referring to the correction coefficient.

15. The magnetic sensor device according to claim 14, wherein
the correction coefficient varies depending on the strength of the component of the magnetic field applied to the magnetic sensor, and
the processor generates the correction coefficient by changing the strength of the additional magnetic field.

16. The magnetic sensor device according to claim 1, wherein
the magnetic sensor includes a magnetic detection element, and a yoke formed of a soft magnetic body, and
the yoke is configured to generate an output magnetic field component that is to be detected by the magnetic detection element, based on the component of the magnetic field applied to the magnetic sensor.

17. The magnetic sensor device according to claim 1, wherein the magnetic sensor includes a magnetoresistive element.

18. The magnetic sensor device according to claim 1, wherein
each of the magnetic sensor and the processor includes a top surface and a bottom surface that face directions opposite to each other,
the magnetic sensor is mounted to the processor in such an orientation that the bottom surface of the magnetic sensor faces the top surface of the processor,
the magnetic field generator includes a coil, and
the coil is disposed between the top surface of the magnetic sensor and the bottom surface of the processor.

19. A magnetic sensor system comprising:
the magnetic sensor device according to claim 1; and
an external processor, wherein
the detection signal includes a first signal, a second signal, and a third signal that have correspondences with components in three mutually different directions of the magnetic field at a reference position,
the external processor generates data on center coordinates of a virtual sphere having a spherical surface in an orthogonal coordinate system defined by three axes indicating values of the first signal, the second signal, and the third signal, the spherical surface approximating a distribution of a plurality of measurement points in a plurality of timings,
each of the plurality of measurement points represents coordinates in the orthogonal coordinate system corresponding to a set of values of the first signal, the second signal, and the third signal at a certain timing, and
the processor of the magnetic sensor device corrects an offset of each of the first signal, the second signal, and the third signal by referring to the data on the center coordinates.

20. The magnetic sensor system according to claim 19, wherein the offset corrected by the processor of the magnetic sensor device includes an offset caused due to a disturbance other than geomagnetism.

21. A correction method for a magnetic sensor configured to detect a magnetic field, the correction method comprising:
applying an additional magnetic field to the magnetic sensor, the additional magnetic field being used to measure sensitivity of the magnetic sensor;
generating first sensitivity that indicates the sensitivity of the magnetic sensor while changing a strength of the additional magnetic field in a first range;
generating second sensitivity that indicates the sensitivity of the magnetic sensor while changing the strength of the additional magnetic field in a second range;
generating a first value indicating a correspondence with a strength of a component of the magnetic field applied to the magnetic sensor, based on the first sensitivity and the second sensitivity;
generating a second value indicating a correspondence with the strength of the component of the magnetic field applied to the magnetic sensor, based on the detection signal of the magnetic sensor; and
correcting an offset of a detection signal based on the first value and the second value.
